(19) United States
(12) Patent Application Publication
(10) Pub. No.: US 2014/0334117 A1
(43) Pub. Date: Nov. 13, 2014

(54) ELECTRIC DEVICE FOR VEHICLE AND MANUFACTURING METHOD OF THE SAME

(71) Applicant: DENSO CORPORATION, KARIYA-CITY (JP)

(72) Inventor: Yoshimasa Sano, Tokoname-city (JP)

(73) Assignee: DENSO CORPORATION, KARIYA-CITY (JP)

(21) Appl. No.: 14/269,522

(22) Filed: May 5, 2014

(30) Foreign Application Priority Data
May 7, 2013 (JP) 2013-097760

(51) Int. Cl. H05K 7/14; H05K 3/00

(52) U.S. Cl. CPC H05K 7/1417; H05K 3/00; H05K 2203/0703; H05K 2203/1377
USPC 361/752; 29/829

(57) ABSTRACT

An electric device for a vehicle includes: a circuit board having an attachment unit, which is attachable to a vehicular attachment unit, wherein an electric element for providing an electric circuit is mounted on the circuit board; and a shrinkage cover covering a surface of the electric element and a surface of the circuit board. The attachment unit of the circuit board is directly attachable to the vehicular attachment unit with a fastening element.

### CROSS REFERENCE TO RELATED APPLICATION

This application is based on Japanese Patent Application No. 2013-97760 filed on May 7, 2013, the disclosure of which is incorporated herein by reference.

### TECHNICAL FIELD

The present disclosure relates to an electric device for a vehicle and a manufacturing method of the same.

### BACKGROUND

Conventionally, an electric device for a vehicle includes a circuit board, on which an electric element for providing an electric circuit is mounted, a casing for accommodating and supporting the circuit board, and a bracket for attaching the casing to an attachment unit of the vehicle. JP-A-2010-40992 teaches that the circuit board and the electric element are arranged in a forming mold, and the casing is formed together with the circuit board and the electric element integrally by a low-pressure transfer molding method with thermo-setting resin components.

Here, in general, a conventional electric device includes a casing for accommodating a circuit board and a bracket for attaching the casing to an attachment unit of the vehicle. Accordingly, the number of elements in the electric device may easily increase, and a structure of the electric device may be complicated. Thus, it is required to simplify the structure of the device.

### SUMMARY

It is an object of the present disclosure to provide an electric device and a manufacturing method of the same. A structure of the electric device is simplified, and the number of elements in the electric device is reduced.

According to a first aspect of the present disclosure, an electric device for a vehicle includes: a circuit board having an attachment unit, which is attachable to a vehicular attachment unit, wherein an electric element for providing an electric circuit is mounted on the circuit board; and a shrinkage cover covering a surface of the electric element and a surface of the circuit board. The attachment unit of the circuit board is directly attachable to the vehicular attachment unit with a fastening element.

In the above electric device, the circuit board includes the attachment unit, which is attachable to the vehicle attachment unit. The attachment unit is attached to the vehicle attachment unit with the fastening element. Further, the circuit board and the electric element mounted on the circuit board are protected by the cover, which seals the surface thereof. Accordingly, it is not necessary to prepare a casing and a bracket in a conventional electric device. Thus, the structure of the electric device is simplified, and the number of elements in the electric device is reduced.

According to a second aspect of the present disclosure, a manufacturing method of an electric device for a vehicle, which includes: a circuit board having an attachment unit attachable to a vehicular attachment unit, wherein an electric element for providing an electric circuit is mounted on the circuit board; and a cover covering a surface of the electric element and a surface of the circuit board, the manufacturing method includes: plating with metal on the attachment unit so that a metal thick film is formed, and mounting the electric element on the circuit board so that the circuit board is prepared; accommodating the circuit board, on which the electric element is mounted, in the cover made of resin or rubber and having a pouch shape; thermally press-bonding a periphery of the cover along an outer circumference of an opening of the cover to the circuit board; and shrinking the cover.

In the above manufacturing method, the structure of the electric device is simplified, and the number of elements in the electric device is reduced.

According to a third aspect of the present disclosure, a manufacturing method of an electric device for a vehicle, which includes: a circuit board having an attachment unit attachable to a vehicular attachment unit, wherein an electric element for providing an electric circuit is mounted on the circuit board; and a cover covering a surface of the electric element and a surface of the circuit board, the manufacturing method includes: sticking a sheet of the cover to a surface of the circuit board, on which the electric element is mounted; thermally press-bonding an outer periphery of the cover to the circuit board; shrinking the cover; and attaching a metal member for reinforcing the attachment unit in a through hole in the attachment unit of the circuit board from an outside of the cover.

In the above manufacturing method, the structure of the electric device is simplified, and the number of elements in the electric device is reduced.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram showing a plan view of an electric device for a vehicle according to a first embodiment;

FIG. 2 is a diagram showing a side view of the electric device for the vehicle according to the first embodiment;

FIG. 3 is a diagram showing a bottom view of the electric device for the vehicle according to the first embodiment;

FIG. 4 is a flowchart showing a manufacturing method of the electric device for the vehicle according to the first embodiment;

FIG. 5A is a diagram showing a circuit board formed at a circuit board forming step of the manufacturing method of the electric device for the vehicle according to the first embodiment, and FIG. 5B is a diagram showing a cross sectional view of the circuit board taken along line VB-VB in FIG. 5A;

FIG. 6A is a diagram showing a cover formed at a circuit board accommodation step of the manufacturing method of the electric device for the vehicle according to the first embodiment, and FIG. 6B is a diagram showing a cross sectional view of the cover taken along line VIB-VIB in FIG. 6A;

FIG. 7 is a diagram showing a plan view of a work at circuit board forming step of the manufacturing method of the electric device for the vehicle according to the first embodiment;

FIG. 8 is a diagram showing a side view of the work after the circuit board forming step of the manufacturing method of the electric device for the vehicle according to the first embodiment;

FIG. 9 is a diagram showing the work at a cover press-bonding step of the manufacturing method of the electric device for the vehicle according to the first embodiment;

FIG. 10 is a diagram showing a cross sectional view of the work taken along line X-X in FIG. 9;

FIG. 11 is a diagram showing a plan view of the work at a cover shrinking step of the manufacturing method of the electric device for the vehicle according to the first embodiment;

FIG. 12 is a diagram showing a side view of the work at the cover shrinking step of the manufacturing method of the electric device for the vehicle according to the first embodiment;

FIG. 13 is a diagram showing a bottom view of the work at the cover shrinking step of the manufacturing method of the electric device for the vehicle according to the first embodiment;

FIG. 14 is a diagram showing a state of the electric device for the vehicle before attaching to an attachment unit of the vehicle, according to the first embodiment;

FIG. 15 is a diagram showing a state of the electric device for the vehicle after attaching to the attachment unit of the vehicle, according to the first embodiment;

FIG. 16 is a diagram showing a plan view of the work at a cover shrinking step of the manufacturing method of the electric device for the vehicle according to a first modification of the first embodiment;

FIG. 17 is a diagram showing a side view of the work at the cover shrinking step of the manufacturing method of the electric device for the vehicle according to the first modification of the first embodiment;

FIG. 18 is a diagram showing a bottom view of the work at the cover shrinking step of the manufacturing method of the electric device for the vehicle according to the first modification of the first embodiment;

FIG. 19 is a diagram showing a plan view of an electric device for a vehicle according to a second embodiment;

FIG. 20 is a diagram showing a bottom view of the electric device for the vehicle according to the second embodiment;

FIG. 21 is a diagram showing a side view of the electric device for the vehicle according to the second embodiment;

FIG. 22 is a flowchart showing a manufacturing method of the electric device for the vehicle according to the second embodiment;

FIG. 23A is a diagram showing a plan view of a circuit board formed by the manufacturing method of the electric device for the vehicle according to the second embodiment, and FIG. 23B is a diagram showing a cross sectional view of the circuit board taken along line XXIIIB-XXIIIB in FIG. 23A;

FIG. 24 is a diagram showing a cover bonding step of the manufacturing method of the electric device for the vehicle according to the second embodiment;

FIG. 25 is a diagram showing a plan view of the work after the cover bonding step of the manufacturing method of the electric device for the vehicle according to the second embodiment;

FIG. 26 is a diagram showing a bottom view of the work after the cover bonding step of the manufacturing method of the electric device for the vehicle according to the second embodiment;

FIG. 27 is a diagram showing a plan view of the work after the cover press-bonding step of the manufacturing method of the electric device for the vehicle according to the second embodiment;

FIG. 28 is a diagram showing a front view of the work viewing from a connector side after the cover press-bonding step of the manufacturing method of the electric device for the vehicle according to the second embodiment;

FIG. 29 is a diagram showing a plan view of the work at the cover shrinking step of the manufacturing method of the electric device for the vehicle according to the second embodiment;

FIG. 30 is a diagram showing a front view of the work viewing from a connector side at the cover shrinking step of the manufacturing method of the electric device for the vehicle according to the second embodiment;

FIG. 31 is a plan view of the work at a metallic member attaching step of the manufacturing method of the electric device for the vehicle according to the second embodiment;

FIG. 32A is a diagram showing a side view of the electric device for the vehicle at the metallic member attaching step of the manufacturing method according to the second embodiment before attaching the metallic member, and

FIG. 32B is a diagram showing the side view of the electric device for the vehicle after attaching the metallic member;

FIG. 33A is a diagram showing a side view of the electric device for the vehicle at the metallic member attaching step of the manufacturing method according to the second modification of the first embodiment before attaching the metallic member, and FIG. 33B is a diagram showing the side view of the electric device for the vehicle after attaching the metallic member;

FIG. 34 is a diagram showing a front view of the work viewing from a connector side at the metallic member attaching step of the manufacturing method according to the third modification of the first embodiment; and

FIG. 35 is a diagram showing a side view of the electric device at the metallic member attaching step of the manufacturing method according to the third modification of the first embodiment after the metallic member is attached.

### DETAILED DESCRIPTION

### First Embodiment

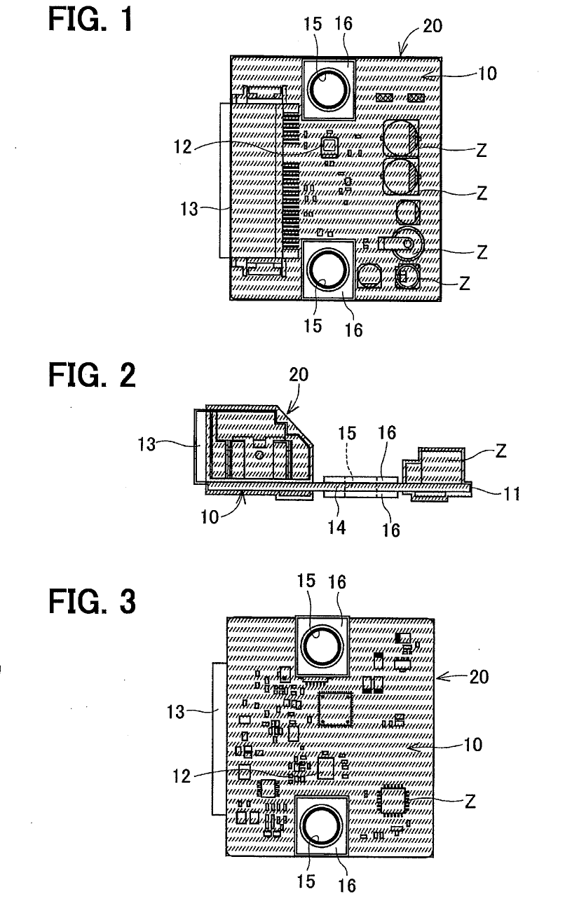

An electric device for a vehicle according to the first embodiment is suitably used for an air bag ECU. As shown in FIGS. 1 to 3, the electric device includes a circuit board 10 and a cover 20.

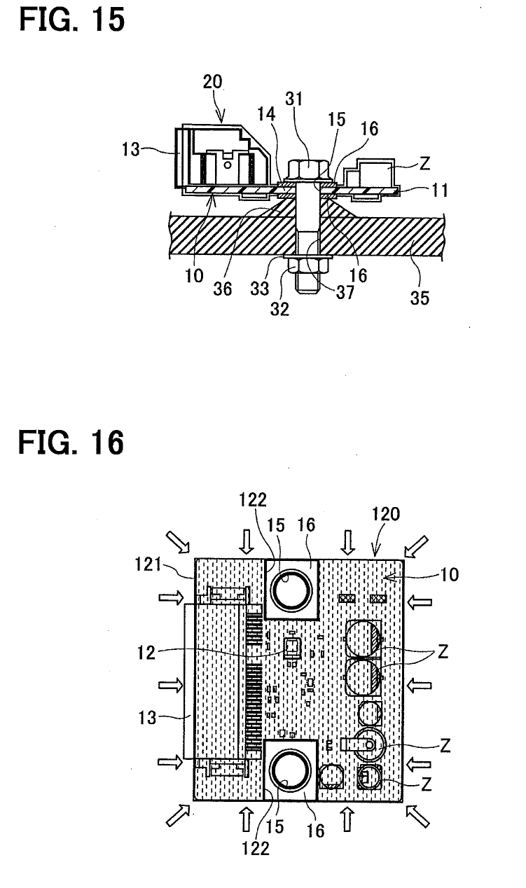

The circuit board 10 is a substrate of the air bag ECU for detecting acceleration of the vehicle and for executing an inflation control process of the air bag based on a detection result. The circuit board 10 includes a printed board 11, on which a printed wiring (not shown) is formed, an acceleration sensor 12 and a connector 13, which are mounted on the printed board 11, and an electric element Z. The printed board 11 is made of resin and has a plate shape with a rectangular shape. An attachment unit 14 as a device side attachment unit to be attached to an attachment unit 36 of the vehicle as a vehicle side attachment unit, as shown in FIGS. 14 and 15, is arranged on each side of the printed board 11 in a longitudinal direction.

Each attachment unit 14 includes a through hole 15, through which an attachment bolt 31 as a press-bonding member is inserted. The attachment unit 14 is reinforced with a metallic thick film 16, which is formed by plating a metal around the through hole 15 on a front surface and a rear surface of the printed board 11. the metallic thick film 16 is connected to the printed wiring. The thickness of the metallic thick film 16 is larger than the thickness of the printed wiring.

The electric circuit of the circuit board 10 includes the printed wiring made of predetermined metallic material on the printed board 11 and various electric elements arranged on the printed board 11 such as an acceleration sensor 12, a connector 13 and other electric elements Z. The acceleration sensor 12 is a G sensor for detecting acceleration of the vehicle as one of physical quantities of behavior of the vehicle. The connector 13 is connected to the electric circuit and disposed on the circuit board 10. The connector 13 is connected to a vehicular wiring such as a vehicular harness.

The cover 20 is made of resin and has a pouched shape. The cover 20 accommodates the circuit board 10 and various electric elements 12, 13, Z, which are arranged on the circuit board 10, therein. After a portion around an opening of the cover 20 is thermally press-bonded, an inside of the cover 20 is evacuated so that the cover 20 is shrunk. Thus, the circuit board 10 and the electric element 12, 13, Z protected by the cover 20 are prevented from damage and have a water proof property. Here, the resin of the cover 20 is, for example, polyolefin resin, fluorine resin, silicone resin or the like.

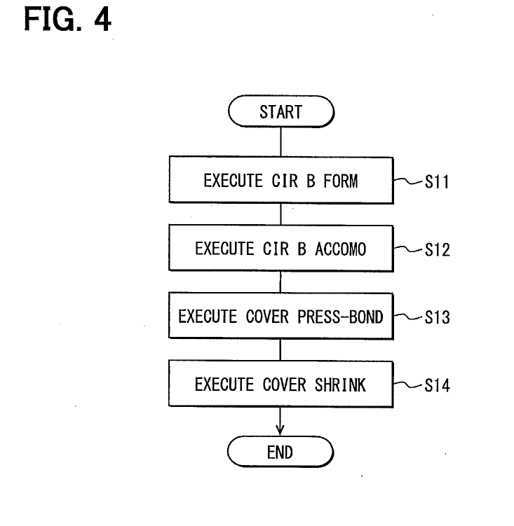

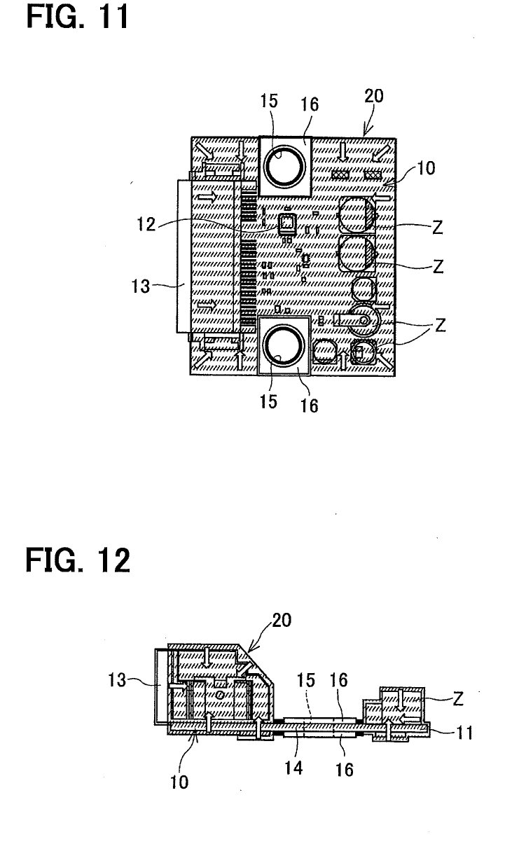

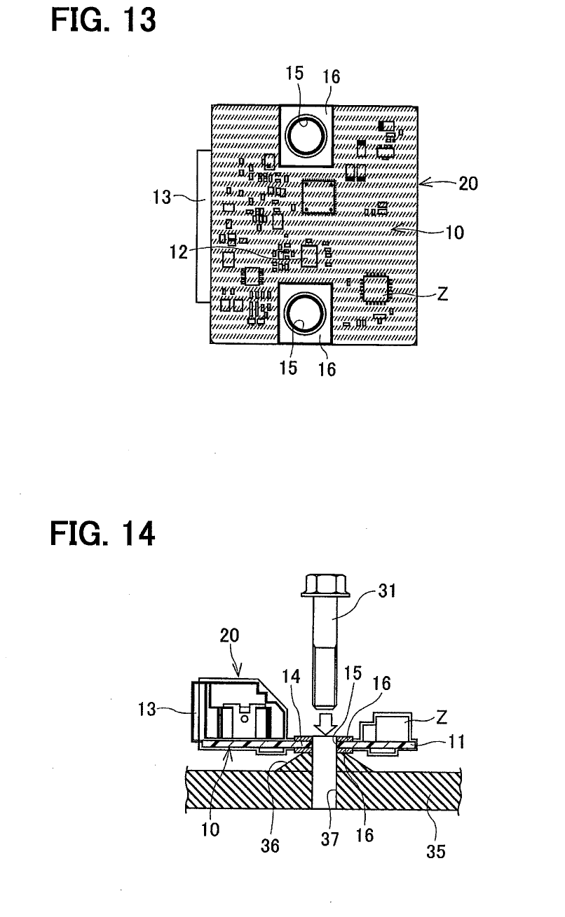

Next, a manufacturing method of the electric device for the vehicle according to the present embodiment will be explained with reference to FIGS. 4 to 13. As shown in FIG. 4, the device is manufactured by executing a circuit board forming step S11, a circuit board accommodating step S12, a cover press-bonding step S13 and a cover shrinking step S14 in this order.

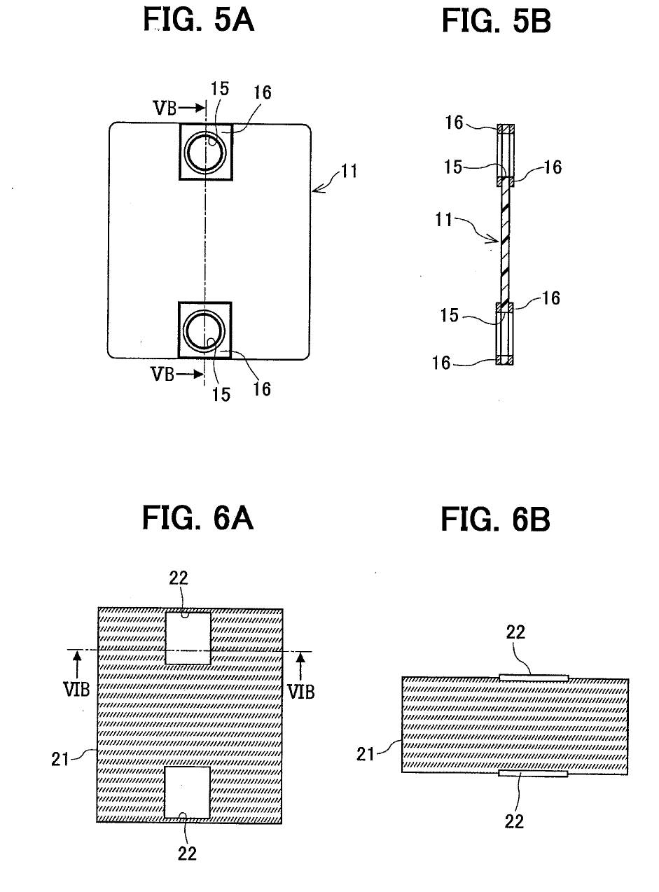

At the circuit board forming step S11, as shown in FIGS. 5A and 5B, at a step for forming the printed board 11, the attachment unit 14 having the through holes 15 on both sides in the longitudinal direction of the unit 14 is formed. Further, the metallic thick film 16 is formed by plating with metal around the through holes 15 of the attachment unit 14. After that, various electric elements such as the acceleration sensor 12 and the connector 13 are mounted on the printed board 11 at predetermined positions, respectively, so that the circuit board 10 is formed.

At the circuit board accommodating step S12, as shown in FIGS. 6A and 6B, the cover 20 having a pouched shape and made of resin is prepared. The cover 20 has the dimensions capable of accommodating the circuit board 10. The cover 20 includes the opening 21 on one end, i.e., a left side in FIG. 6A. Further, another opening 22 having a rectangular shape is formed on each side in the longitudinal direction (i.e., the up-down direction in FIG. 6A) of the cover 20, which corresponds to the attachment unit 14 of the circuit board 10.

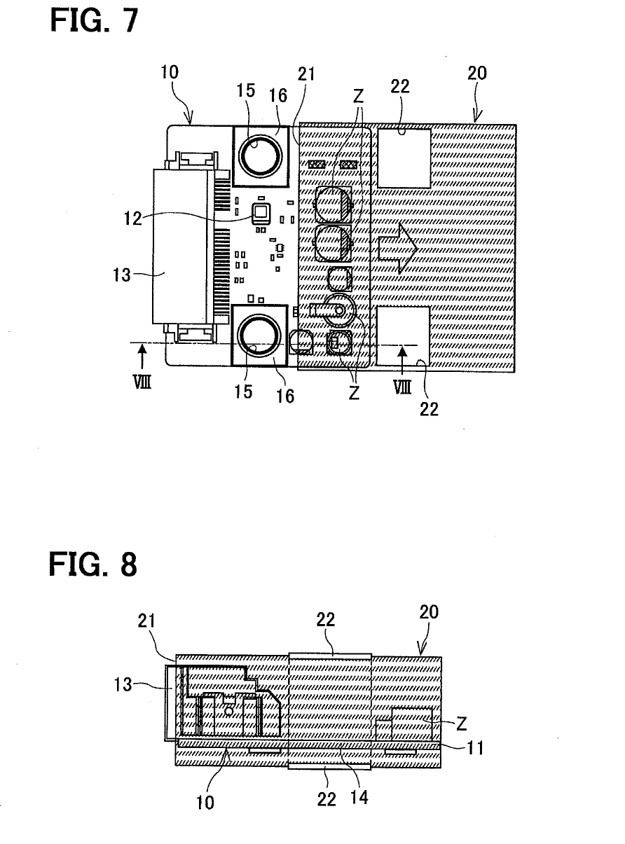

As shown in FIG. 7, the circuit board 10 formed at the circuit board forming step S11 is inserted into the cover through the opening 21 so that the board 10 is accommodated in the cover 20. Thus, as shown in FIG. 8, the circuit board 10 is accommodated in the cover 20 under a condition that the attachment unit 14 and the openings 22 are aligned.

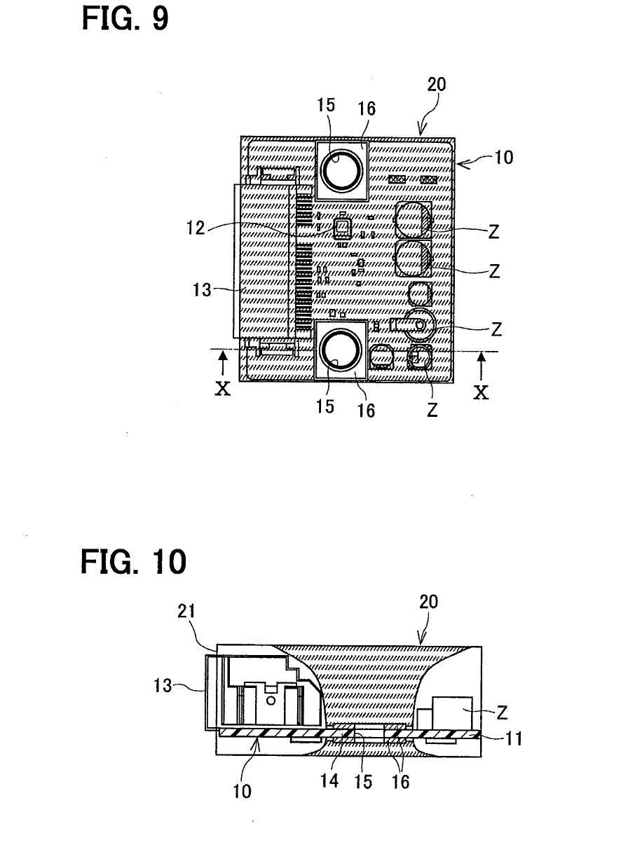

At the cover press-bonding step S13, as shown in FIGS. 9 and 10, a periphery portion along an outer circumference of each opening 22 of the cover 20 is thermally clamped (press-bonded) to the outer periphery of the attachment unit 14. Further, the periphery portion of the opening 21 of the cover 20 is also thermally press-bonded to the circuit board 10. Thus, three openings 21, 22 other than a part of the opening 21 of the cover 20 are sealed.

At the cover shrinking step S14, with using a vacuum pump (not shown), the inside of the cover 20 is evacuated through the opening 21. Thus, as shown in FIGS. 11 to 13, the cover 20 is shrunk in whole. Thus, in the present embodiment, a packaging process is executed using the cover 20 as a vacuum seal. Thus, the cover 20 adheres tightly to the surface of various electric elements 12, 13, Z and the surface of the circuit board 10 so that the cover 20 seals the various electric elements 12, 13, Z and the circuit board 10. Then, if necessary, a finishing process is executed, so that the electric device for the vehicle is completed, as shown in FIGS. 1 to 3.

As shown in FIGS. 14 and 15, the electric device for the vehicle according to the present embodiment is attached to the attachment unit 36 of the vehicle, which is arranged on a vehicle frame 35 made of metal, with an attachment bolt 31 and a nut 32 as a fastening member. Specifically, the electric device is arranged under a condition that a pair of attachment holes 37, which are arranged at two points of the attachment unit 36, and two through holes 15 arranged at two points of the circuit board 10 are aligned to each other, respectively.

A shaft of the attachment bolt 31 is inserted into the through hole 15 and the attachment hole 37. Then, a top end of the shaft of the attachment bolt 31, which protrudes from the attachment hole 37, is fastened with the nut 32 so that the electric device is attached to the vehicle. Thus, the attachment unit 14 of the circuit board 10 is directly attached to the attachment unit 36 of the vehicle. Here, the top of the attachment bolt 31 contacts the metallic thick film 16, which is arranged on the surface of the attachment unit 14. The nut 32 fastened to the top end of the attachment bolt 31 electrically connects with the vehicle frame 35 via a washer 33. Thus, the electric circuit as a printed wiring of the circuit board 10 electrically connects with the vehicle frame 35 via the metallic thick film 16, the attachment bolt 31, the nut 32 and the washer 33, so that the electric circuit connects to ground, i.e., a body of the vehicle.

In the electric device for the vehicle according to the present embodiment, the circuit board 10 includes the attachment unit 14 to be attached to the attachment unit 36 of the vehicle. The attachment unit 14 is directly attached to the attachment unit 36 of the vehicle with the bolt 31 and the nut 32. The circuit board 10 and the electric elements mounted on the circuit board 10 are protected by the cover 20, which seals the surface of the circuit board 10 and the electric elements. Accordingly, it is not necessary to prepare a casing and a bracket in a conventional electric device. Accordingly, the structure of the electric device is simplified, and the number of elements of the electric device is much reduced.

The attachment 14 of the electric device includes the through hole 15, through which the bolt 31 is inserted. The through hole 15 is reinforced with the metallic thick film 16, which is arranged around the hole 15. Thus, the attachment unit 14 of the circuit board 20 is fixed to the attachment unit 36 of the vehicle surely and strongly.

In the present embodiment, the fastening member is provided by the attachment bolt 31, which is to be inserted into the through hole 15 of the attachment unit 14 and the attachment hole 37 of the attachment unit 36 of the vehicle, and the nut 32 to be attached to the bolt 31. Thus, the electric circuit (i.e., the printed wiring) of the circuit board 10 and the vehicle frame 35 are connected to each other via the metallic thick film 16, the attachment bolt 31 and the nut 32. Thus, it is not necessary to prepare an additional wiring for grounding to the body of the vehicle. The number of elements in the electric device is reduced, and the manufacturing cost of the electric device is also reduced. Further, the fastening manner of the bolt 31 and the nut 32 provides large fastening force and strong fixation. Thus, the behavior of the vehicle is transmitted to the circuit board 10 with high accuracy. Furthermore, the bolt 31 and the nut 32 are general purpose elements, and therefore, the manufacturing cost is reduced.

In the present embodiment, the cover 20 is made of resin and has a sac-like shape or a pouch shape. Accordingly, the circuit board 10 and various electric elements 12, 13, Z accommodated in the cover 20 are easily sealed. Thus, the circuit board 10 and various electric elements 12, 13, Z accommodated in the cover 20 are protected from water, so that the electric device has high water protection. Further, the damage of the electric device is prevented.

The manufacturing method of the electric device for the vehicle according to the present embodiment provides the electric device having the simple structure and the small number of elements, which is easily and simply manufactured.

(First Modification)

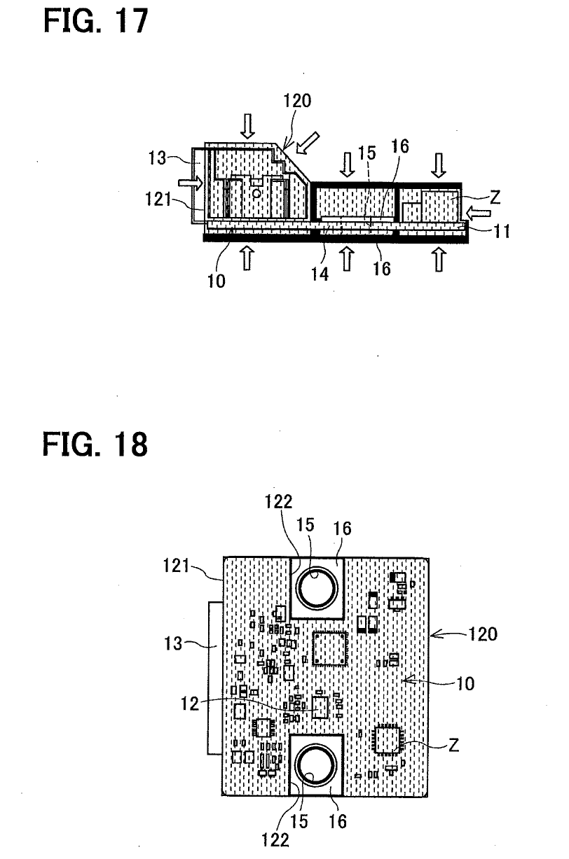

A first modification of the above embodiment will be explained with reference to FIGS. 16 to 18. In the above embodiment, at the cover shrinking step S14 in the manufacturing method of the electric device for the vehicle, the packaging process with using the vacuum sealing method is performed. Alternatively, in the first modification, the packaging process may be performed with using heat shrinkage of a cover 120.

In the first modification, the cover 120 is made of rubber and has a sac-like shape having a predetermined thickness. The cover 120 has the sac-like shape with three openings 121, 122, which is similar to the cover 20 according to the first embodiment. The cover 120 is made of rubber having a contractile property (i.e., a shrinkage property), which is different from the cover 20, and has the thickness larger than the cover 20.

The cover shrinking step S14 according to the first modification is performed after the circuit board forming step S11, the circuit board accommodating step S12, and the cover press-bonding step S13, similar to the first embodiment. Thus, after the cover press-bonding step S13, the periphery of the cover 120 around the opening 121, 122 is thermally adhered to the circuit board 10 so that three openings 121, 122 of the cover 120 are sealed.

Under the above situation, when the cover shrinking step S14 in the first modification starts, the cover 120 made of rubber material and having a pouch shape is shrunk as a whole by the heating process, as shown in FIGS. 16-18. At this time, since the cover 120 is made of rubber material, and has a thickness larger than the cover 20 according to the first embodiment, a clearance between the cover 120 and the surface of various electric elements 12, 13, Z and the circuit board 10 is formed, which is different from the first embodiment. Specifically, the cover 120 covers the surface of various electric elements 12, 13, Z and the circuit board 10, so that the cover 120 has a flat surface, which does not fit the convexity and concavity on the surface of the various electric elements 12, 13, Z and the circuit board 10.

Thus, in the first modification, the cover 120 is made of rubber material having a heat-shrinkable property and has a pouch shape. Further, the cover 120 has a thickness larger than the cover 20 made of resin according to the first embodiment. Accordingly, the shrinkage rate of the cover 120 is easily controlled so as not to adhere to the various electric elements 12, 13, Z. Thus, the clearance between the cover 120 and the surface of various electric elements 12, 13, Z and the circuit board 10 is surely and easily secured. Thus, the cover 120 maintains a flat shape, so that a part of the surface of the cover 120, on which a label is attached, is easily secured. Further, since there is no convexity and concavity, a damage caused by a scratch is prevented.

The rubber material of the cover 120 having the heat shrinkage property is, for example, silicon rubber, fluoride silicon rubber, or neoprene rubber. The thickness of the cover 20 is determined according to the heat shrinkage rate of the rubber material.

### Second Embodiment

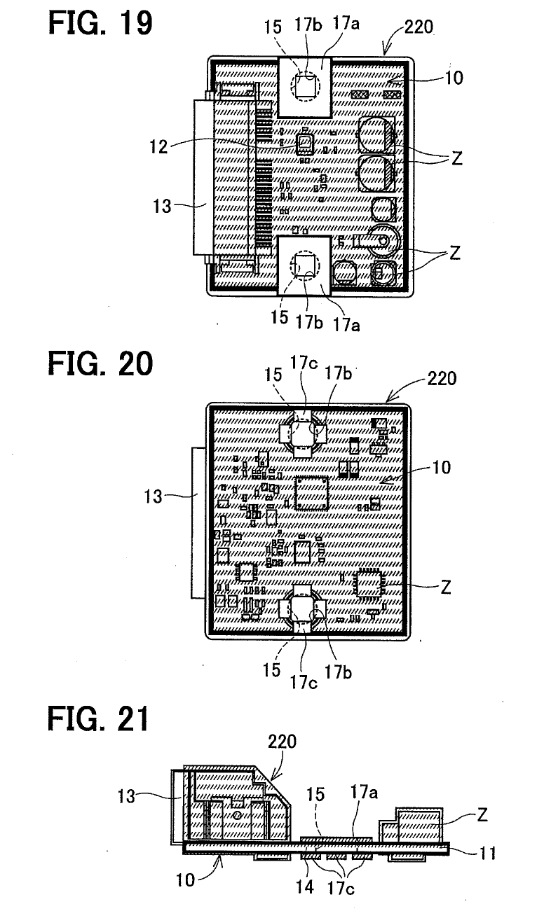

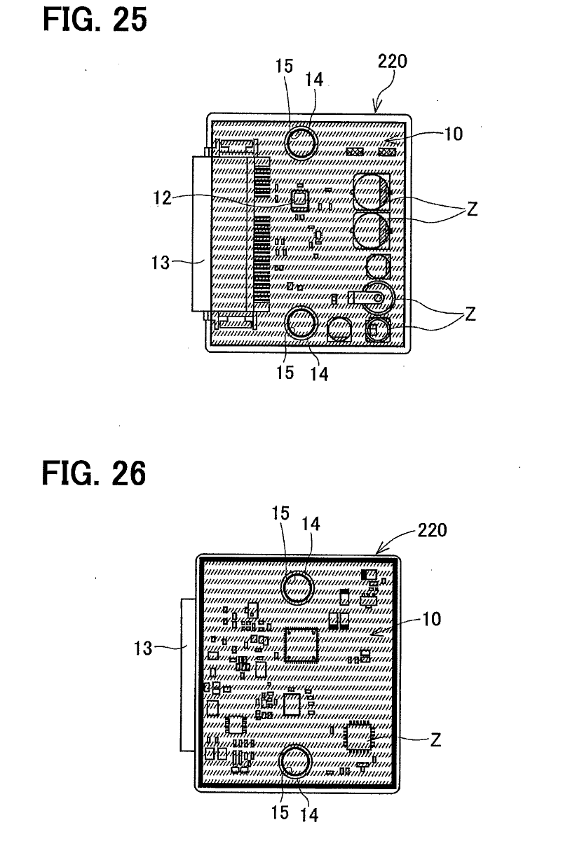

An electric device for a vehicle according to a second embodiment will be explained with reference to FIGS. 19 to 32. The electric device according to the second embodiment includes the circuit board 10 and the cover 220, as shown in FIGS. 19 to 21. The electric device according to the second embodiment is similar to the first embodiment except for a metal plate 17 as a metal member with a hook. Further, the cover 220 is different from the cover 20 according to the first embodiment.

The circuit board 10 according to the second embodiment includes the printed board 11, the acceleration sensor 12 and the connector 13, which are mounted on the printed board 11, and other electric elements Z, similar to the circuit board 10 according to the first embodiment. Here, the through hole 15 is formed on both sides in the attachment unit 14 along the longitudinal direction of the printed board 11. The metal plate 17 having the hook as a metal member for reinforcing the attachment unit 14 is inserted in the through hole 15.

The metal plate 17 includes a base unit 17a having a rectangular shape with a through hole 17b at a center of the base unit 17, and four hooks 17c extending from a periphery around the through hole 17b in an axial direction. The metal plat 17 is attached to each attachment unit 14 such that four hooks 17c are inserted in the attachment unit 14 from one side thereof such as an upper side or a front surface in FIG. 21. Then, four tops of the hooks 17c protruded from the other side opposite to the one side such as a lower side or a back surface are bent to the outside in the radial direction, so that the metal plate 17 is attached to the attachment unit 14.

The cover 220 according to the second embodiment includes two sheets made of resin and having a rectangular sheet shape. The resin material of the cover 220 may be the same as the cover 20 according to the first embodiment. Each sheet of the cover 220 is bonded to a respective surface of the printed board 11. The outer periphery of the cover 220 bonded to both of the front surface and the back surface of the printed board 11 is thermally press-bonded to the outer periphery of the printed board 11. Then, similar to the first embodiment, the inside of the cover 220 is vacuumed so that the cover 220 is shrunk. Thus, the electric elements 12, 13, Z and the circuit board 10 covered with the cover 220 are protected from damage and have a water proof property.

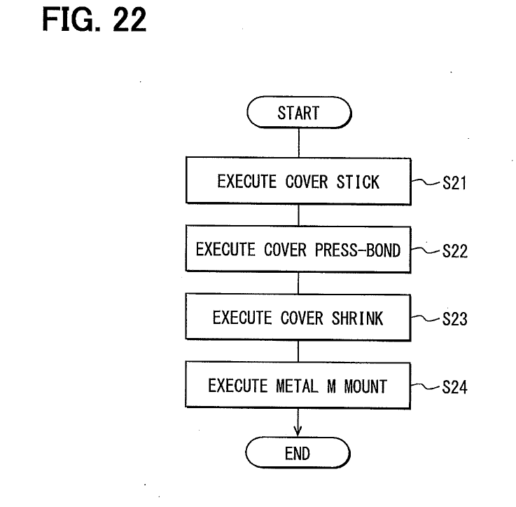

Next, a manufacturing method of the electric device for the vehicle according to the second embodiment will be explained with reference to FIGS. 22 to 32. The electric device according to the present embodiment is manufactured by executing the cover sticking step S21, the cover press-bonding step S22, the cover shrinking step S23, and the metal member mounting step S24 in this order.

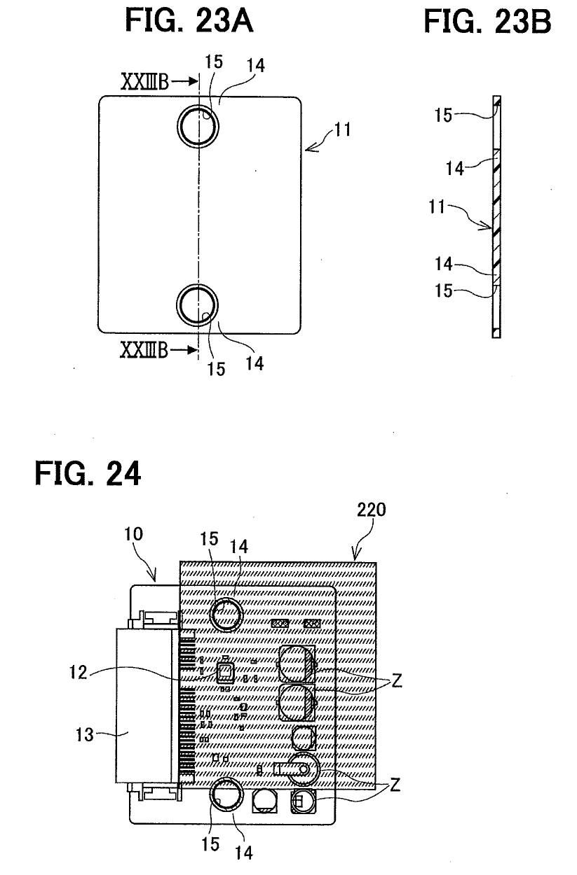

At the cover sticking step S21, as shown in FIGS. 23A and 23B, in a manufacturing process of the printed board 11, the printed board 11 is prepared such that the attachment unit 14 having the through hole 15 on both sides in the longitudinal direction thereof is formed in the printed board 11. The electric elements 12, 13, Z are mounted on the printed board 11 at certain positions, respectively. After that, as shown in FIGS. 24 to 26, the cover 220 made of resin and having a rectangular sheet shape is stuck to each side of the circuit board 10, on which the electric elements 12, 13, Z are mounted.

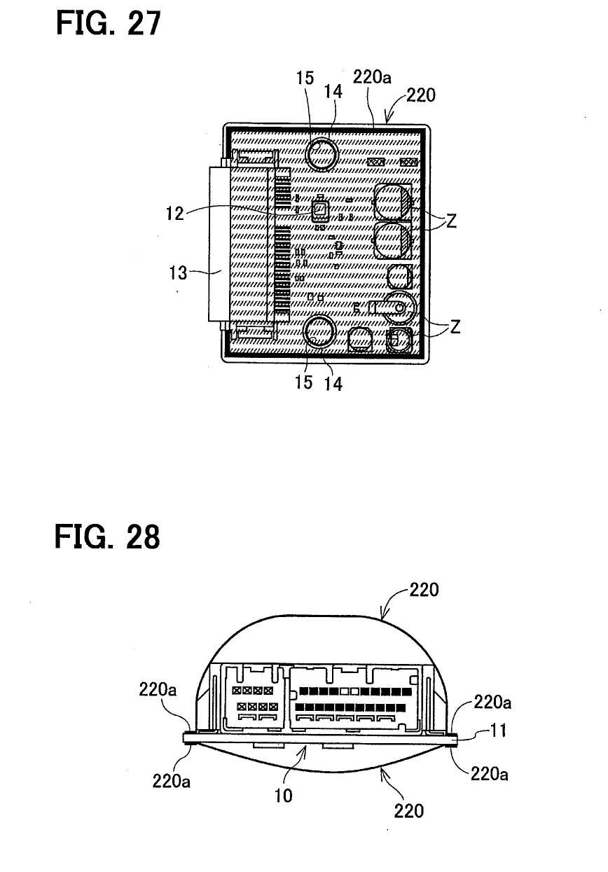

At the cover press-bonding step S22, the outer periphery of each sheet of the cover 220 is thermally press-bonded to the outer periphery of the circuit board 10. Specifically, as shown in FIGS. 27 and 28, the outer periphery of the cover 220 stuck to the front surface of the printed board 11 and the periphery of the cover 220 around the through hole 15 are thermally press-bonded to the outer periphery of the printed board 11 and the periphery of the board 11 around the through hole 15. Further, as shown in FIG. 28, the outer periphery 220a of the cover 220 stuck to the back surface of the printed board 11 and the periphery of the cover 220 around the through hole 15 are thermally press-bonded to the outer periphery of the printed board 11 and the periphery of the board 11 around the through hole 15. Thus, the outer periphery 220a of the cover 220 and the periphery of the cover 220 around the through hole 15 are sealed except for a part of the cover 220.

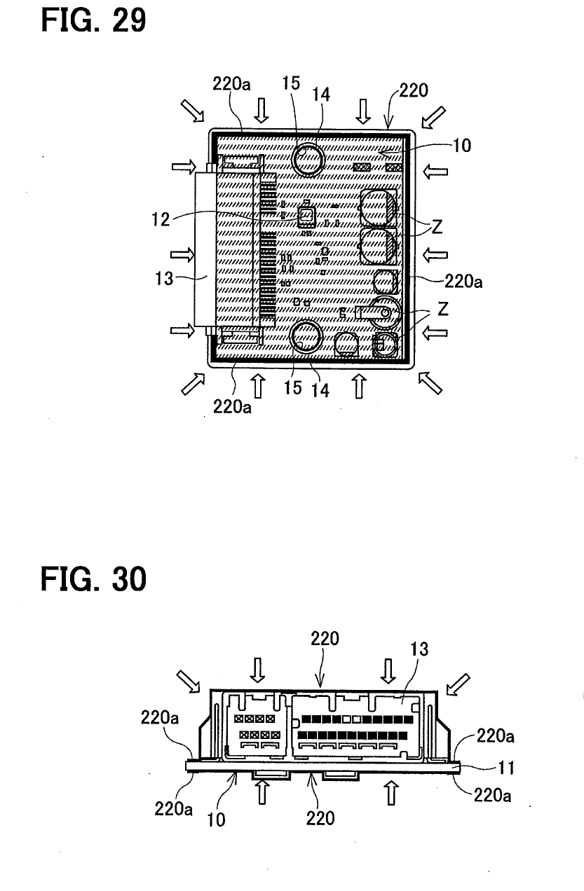

At the cover shrinking step S23, the inside of the cover 220 is vacuumed from the opening 221 with a vacuum pump (not shown), for example. As shown in FIGS. 29 and 30, the cover 220 is shrunk as a whole. Specifically, similar to the first embodiment, the package processing with using the vacuum package of the cover 220 is utilized in the second embodiment. Thus, the cover 220 is adhered to the surface of the electric elements 12, 13, Z and the circuit board 10 so that the cover 220 seals the electric elements 12, 13, Z and the circuit board 10.

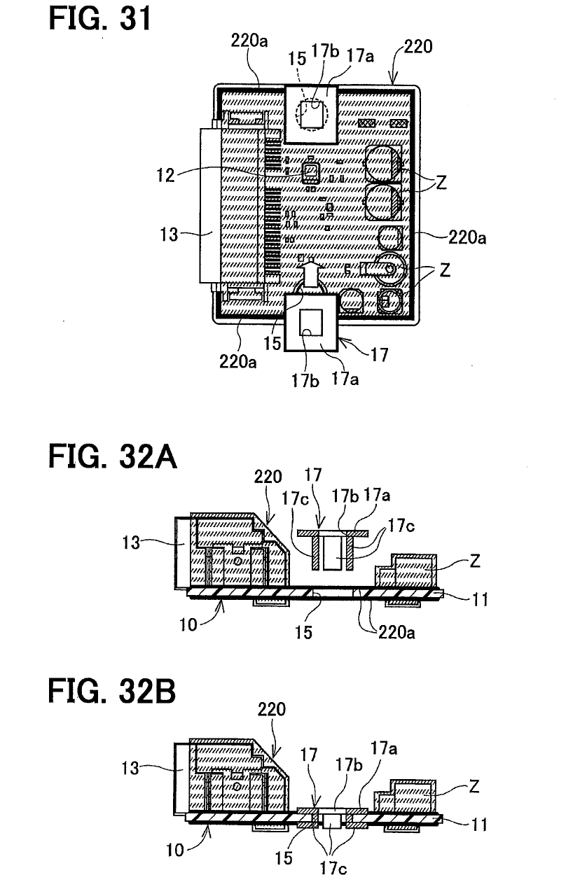

At the metal member mounting step S24, as shown in FIGS. 31, 32A and 32B, the metal plate 17 having the hook as a metal member for reinforcing is mounted in the through hole 15 from an outside of the cover 220. The through hole 15 is formed in the attachment unit 14 of the circuit board 10. In this case, the metal plate 17 having the hook is mounted in the attachment unit 14 such that four hooks 17c are inserted into the through hole 15 from one side of the attachment unit 14 (i.e., the upper surface or the front surface in FIG. 32), and tops of the hooks 17c protruded from the other side of the unit 14 (i.e., the lower surface or the back surface in FIG. 32) are bent to the outside in the radial direction. Here, although each through hole 15 is covered with the cover 220, the cover 220 easily breaks when the hooks 17c is inserted into the through hole 15. Therefore, the metal plate 17 with the hooks is easily attached to the unit 14. After that, if necessary, a finishing process is performed, so that the electric device for the vehicle shown in FIGS. 19 to 21 is completed.

Thus, the electric device for the vehicle according to the present embodiment is mounted to the attachment unit 36 of the vehicle, which is arranged on the vehicle frame 35 made of metal, via a fastening member such as the bolt 31 and the nut 32, similar to the first embodiment, as shown in FIGS. 14 and 15.

Thus, in the electric device for the vehicle according to the second embodiment, the circuit board 10 includes the attachment unit 14 to be attached to the attachment unit 36 of the vehicle. The attachment unit 14 is directly attached to the attachment unit 36 with the bolt 31 and the nut 32. Accordingly, the structure of the electric device is simplified, and the number of elements in the electric device is reduced, which are similar to the first embodiment.

The cover 220 according to the second embodiment is made of resin material, and has the rectangular sheet shape. Alternatively, the cover 220 may be made of rubber material having the heat shrinkage property and have the rectangular sheet shape. Further, the cover 220 may be thermally shrunk instead of the vacuum shrinkage process. In this case, the thickness of the cover 220 may be enlarged, so that the effects similar to the first embodiment are obtained.

(Second Modification)

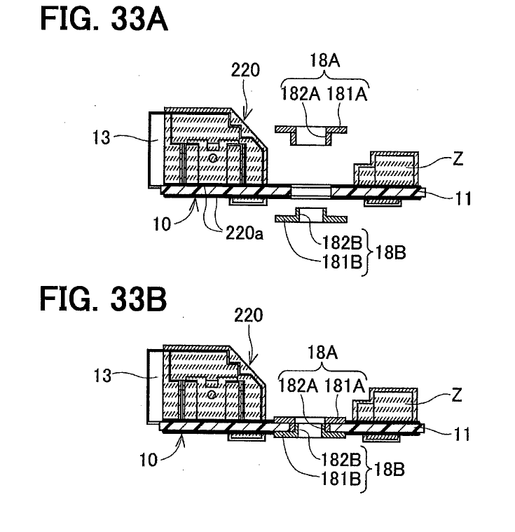

A second modification will be explained with reference to FIGS. 33A and 33B. In the second embodiment, the metal plate 17 having the hook reinforces the attachment unit 14. Alternatively, as shown in FIGS. 33A and 33B, a pair of engagement elements 18A, 18B may be used as the metal member.

In the above case, one engagement element 18A includes a base unit 181A having a rectangular shape with a through hole at a center thereof, and a large diameter ring unit 182A, which is protruded from a periphery around the through hole on one side of the base unit 181A. The large diameter ring unit 182A includes a through hole, which has a circular cross sectional shape, arranged inside of the unit 182A. The other engagement element 18B includes a base unit 181B having a rectangular shape with a through hole at a center thereof, and a small diameter ring unit 182B, which is protruded from a periphery around the through hole on one side of the base unit 181B. The small diameter ring unit 182B is engaged with the inside of the large diameter ring unit 182A.

A pair of the engagement units 18A, 18B is attached to each attachment unit 14 of the printed board 11, as shown in FIGS. 33A and 33B. First, the large diameter ring unit 182A of one engagement element 18A is engaged in the through hole 15 from the front side (i.e., the upper surface in FIG. 33A) of the attachment unit 14 in the printed board 11. Then, the small diameter ring unit 182B of the other engagement element 18B is engaged in the inside of the large diameter ring unit 182A, which is disposed in the through hole 15, from the back side (i.e., the lower surface in FIG. 33A) of the attachment unit 14 in the printed board 11. Thus, the base unit 181A of the engagement unit 18A contacts the front surface of the attachment unit 14, and the base unit 181B of the engagement unit 18B contacts the back surface of the attachment unit 14. Thus, a pair of the engagement units 18A, 18B reinforces the attachment unit 14.

(Third Modification)

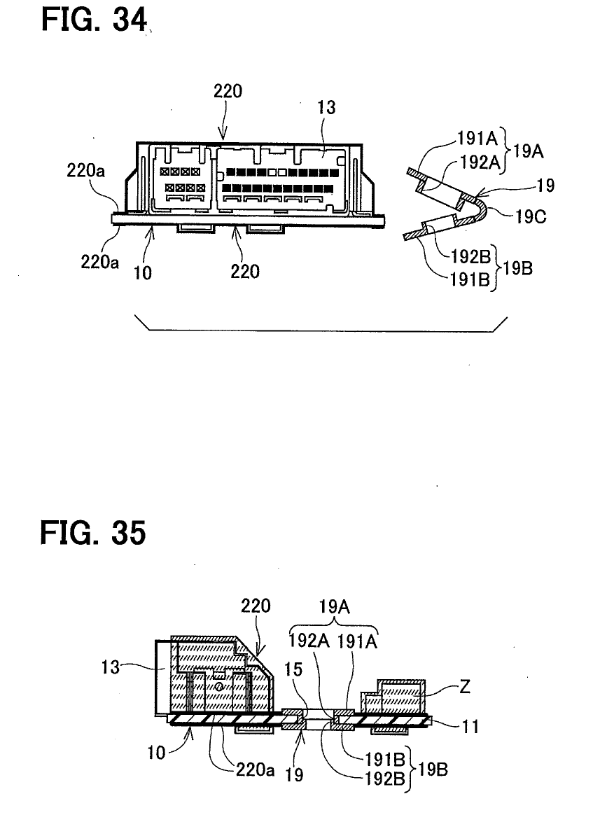

A third modification will be explained with reference to FIGS. 34 and 35. In the third modification, a metal element 19 shown in FIGS. 34 and 35 may be used instead of the pair of engagement units 18A, 18B according to the second modification. The metal element 19 includes a first engagement unit 19A, which is similar to the one engagement unit 18A according to the second modification, a second engagement unit 19B, which is similar to the other engagement unit 18B according to the second modification, and a connector 19C for connecting the first engagement unit 19A and the second engagement unit 19B. Thus, the first engagement unit 19A includes a base unit 191A and a large diameter ring unit 192A. The second engagement unit 19B includes a base unit 191BA and a small diameter ring unit 192B.

The metal element 19 is attached to each attachment unit 14 of the printed board 11, similar to the second modification. As shown in FIG. 35, first, the large diameter ring unit 192A of the first engagement element 19A is engaged in the through hole 15 from the front side (i.e., the upper surface in FIG. 35) of the attachment unit 14 in the printed board 11. Then, the small diameter ring unit 192B of the second engagement element 19B is engaged in the inside of the large diameter ring unit 192A, which is disposed in the through hole 15, from the back side (i.e., the lower surface in FIG. 35) of the attachment unit 14 in the printed board 11. Thus, the metal element 19 reinforces the attachment unit 14, similar to the second modification.

In the metal element 19 according to the third modification, the first engagement unit 19A and the second engagement unit 19B are connected by the connector 19C so that they are integrated with each other. Thus, the handling of the metal element 19 is easy, so that the attachment operation of the metal element 19 to the unit 14 is easily performed.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. An electric device for a vehicle comprising:
a circuit board having an attachment unit, which is attachable to a vehicular attachment unit, wherein an electric element for providing an electric circuit is mounted on the circuit board; and
a shrinkage cover covering a surface of the electric element and a surface of the circuit board,
wherein the attachment unit of the circuit board is directly attachable to the vehicular attachment unit with a fastening element.

2. The electric device according to claim 1,
wherein the attachment unit includes a through hole, through which an attachment bolt as the fastening element is inserted, and
wherein the attachment unit further includes a metal member arranged around the through hole so that the attachment unit is reinforced by the metal member.

3. The electric device according to claim 2,
wherein the fastening element includes the attachment bolt and a nut,
wherein the attachment bolt is inserted into the through hole of the attachment unit and an attachment hole of the vehicular attachment unit, and
wherein the nut is fastened to the attachment bolt.

4. The electric device according to claim 1,
wherein the shrinkage cover is made of resin or rubber, and
wherein the shrinkage cover has a pouch shape or a sheet shape.

5. A manufacturing method of an electric device for a vehicle, which includes: a circuit board having an attachment unit attachable to a vehicular attachment unit, wherein an electric element for providing an electric circuit is mounted on the circuit board; and a cover covering a surface of the electric element and a surface of the circuit board, the manufacturing method comprising:
plating with metal on the attachment unit so that a metal thick film is formed, and mounting the electric element on the circuit board so that the circuit board is prepared;
accommodating the circuit board, on which the electric element is mounted, in the cover made of resin or rubber and having a pouch shape;
thermally press-bonding a periphery of the cover along an outer circumference of an opening of the cover to the circuit board; and
shrinking the cover.

6. A manufacturing method of an electric device for a vehicle, which includes: a circuit board having an attachment unit attachable to a vehicular attachment unit, wherein an electric element for providing an electric circuit is mounted on the circuit board; and a cover covering a surface of the electric element and a surface of the circuit board, the manufacturing method comprising:
sticking a sheet of the cover to a surface of the circuit board, on which the electric element is mounted;
thermally press-bonding an outer periphery of the cover to the circuit board;
shrinking the cover; and
attaching a metal member for reinforcing the attachment unit in a through hole in the attachment unit of the circuit board from an outside of the cover.
